(19) United States
(12) Patent Application Publication
(10) Pub. No.: US 2026/0229287 A1
(43) Pub. Date: Aug. 6, 2026

(54) SUPPLYING HIGH VOLTAGE TO LOCAL SELECT GATES IN MEMORY DEVICES

(71) Applicant: Micron Technology, Inc., Boise, ID (US)

(72) Inventor: Shigekazu Yamada, Tokyo (JP)

(21) Appl. No.: 19/448,625

(22) Filed: Jan. 14, 2026

Related U.S. Application Data
(60) Provisional application No. 63/753,116, filed on Feb. 3, 2025.

(51) Int. Cl. G11C 16/04; G11C 16/08; G11C 16/16; G11C 16/30

(52) U.S. Cl. CPC G11C 16/0433; G11C 16/08; G11C 16/16; G11C 16/30

(57) ABSTRACT

An example memory device includes a memory array and a processing device, operatively coupled to the memory array. The processing device is configured to perform operations, including: identifying a portion of the memory array; causing a first voltage level to be applied to one or more local bitlines of the identified portion of the memory array; causing a second voltage level to be applied to one or more local source lines of the identified portion of the memory array; causing a third voltage level to be applied to a plurality of local select gates of the identified portion of the memory array; causing the plurality of local select gates to transition to a floating state; and causing a fourth voltage level to be applied to one or more wordlines of the identified portion of the memory array.

### REFERENCE TO RELATED APPLICATIONS

This application claims the priority benefit of U.S. Provisional Patent Application No. 63/753,116 filed February 3, 2025, the entirety of which is incorporated herein by reference.

### TECHNICAL FIELD

Implementations of the disclosure relate generally to memory sub-systems, and more specifically, relate to supplying high voltage to local select gates in memory devices.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various implementations of the disclosure.

FIG. 1A illustrates an example computing system that includes a memory sub-system in accordance with implementations of the present disclosure.

FIG. 1B is a block diagram of a memory device in communication with a memory sub-system controller of a memory sub-system, in accordance with implementations of the present disclosure.

FIG. 2 is a schematic of portions of an example array of memory cells, in accordance with implementations of the present disclosure.

FIG. 3 is a schematic of portions of another example array of memory cells, in accordance with implementations of the present disclosure.

FIG. 4 schematically illustrates the voltage levels applied to various components of the memory device, in accordance with implementations of the present disclosure.

FIG. 5 is a flow diagram of an example method of performing erase operations, in accordance with implementations of the present disclosure.

FIG. 6 is a block diagram of an example computer system in which implementations of the present disclosure can operate.

### DETAILED DESCRIPTION

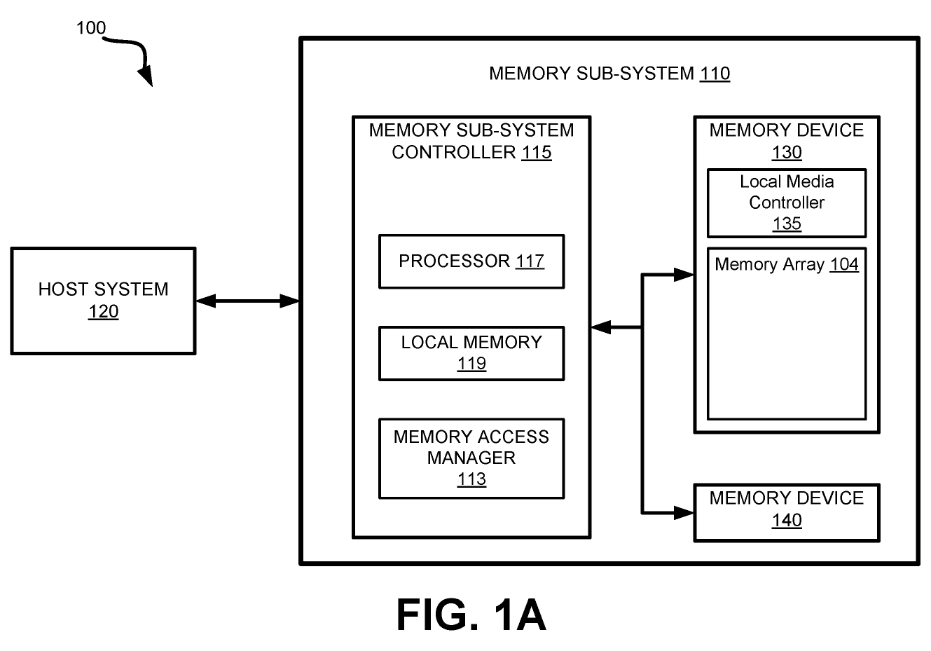

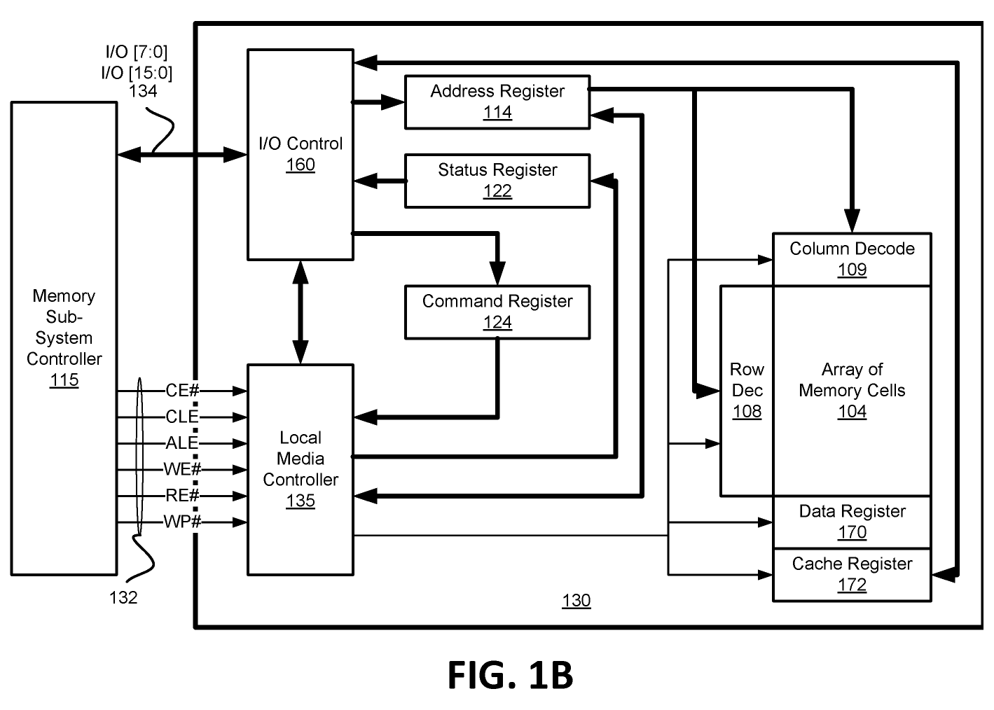

Aspects of the present disclosure are directed to supplying high voltage to select gates in memory devices. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device (e.g., a memory die) can include memory cells arranged in a two-dimensional or a three-dimensional grid. The memory cells are formed onto a silicon wafer in an array of columns and rows. The memory cells are joined by wordlines, which are conducting lines electrically connected to the control gates of the memory cells, and bitlines, which are conducting lines electrically connected to the drain electrodes of the memory cells. The intersection of a bitline and wordline constitutes the address of the memory cell. “Block” refers to a unit of the memory device used to store data and can include a set of memory cells addressable by a shared bitline and multiple wordlines of the memory device.

Some memory devices can include gate-induced drain leakage (GIDL) generator devices that deliberately induce GIDL current for, e.g., performing erase operations, by facilitating the removal of electrons from the floating gates of the memory cells. A high negative voltage is applied to the control gates to facilitate tunneling.

Some memory operations, such as e.g., erase operations, involve applying a high voltage level (e.g., V_{PGM}, which is the programming voltage level) to the bitlines. That voltage would need to go through all select gates without significant drop, which would require driving the local select gates to a higher potential. However, the potential on the local select gates is limited by a certain value (e.g., V_{PGM}).

Systems and methods of the present disclosure facilitate the efficient performance of certain memory operations (e.g., erase operations) by driving the local bitline and the local source line of a selected block to a certain high voltage level (e.g., the programming voltage level V_{PGM}), precharging the local select gates of a selected block to a predetermined voltage level (e.g., 5V), then floating the select gates, which would thus be coupled-up to the local bitline, and completing the erase operation by grounding the wordlines of the selected block, as described in more detail herein below.

Therefore, advantages of the disclosed techniques include achieving higher potential at the local select gates, thus facilitating memory access operations (such as erase operations) and improving the overall efficiency of the memory device.

FIG. 1A illustrates an example computing system 100 that includes a memory sub-system 110 in accordance with implementations of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some implementations, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some implementations, each of the memory devices 130 can include one or more arrays of memory cells such as SLCs, MLCs, TLCs, QLCs, or any combination of such. In some implementations, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some implementations, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another implementation of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some implementations, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some implementations, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some implementations, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some implementations, one or more components of memory sub-system 110 can be omitted.

In some implementations, memory sub-system 110 includes a memory access manager 113. Memory access manager 113 is responsible for handling interactions of memory sub-system controller 115 with the memory devices of memory sub-system 110, such as memory device 130. For example, memory access manager 113 can send memory access commands corresponding to requests received from host system 120 to memory device 130, such as program commands, read commands, or other commands. In addition, memory access manager 113 can receive data from memory device 130, such as data retrieved in response to a read command or a confirmation that a program command was successfully performed. In some implementations, the memory sub-system controller 115 includes at least a portion of the memory access manager 113. For example, the memory sub-system controller 115 can include a processor 117 (e.g., a processing device) configured to execute instructions stored in local memory 119 for performing the operations described herein. In some implementations, the memory access manager 113 is part of the host system 110, an application, or an operating system.

In some implementations, memory device 130 includes local media controller 135 and a memory array 104. As described herein, the memory array 104 can include multiple memory cells organized in multiple blocks of a predefined size, such that each block further includes multiple sub-blocks.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an implementation. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), can be a memory controller or other external host device.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line can be associated with more than one logical row of memory cells and a single data line can be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data can be passed from the cache register 172 to the data register 170 for transfer to the array of memory cells 104; then new data can be latched in the cache register 172 from the I/O control circuitry 160. During a read operation, data can be passed from the cache register 172 to the I/O control circuitry 160 for output to the memory sub-system controller 115; then new data can be passed from the data register 170 to the cache register 172. The cache register 172 and/or the data register 170 can form (e.g., can form a portion of) a page buffer of the memory device 130. A page buffer can further include sensing devices (not shown in FIG. 1B) to sense a data state of a memory cell of the array of memory cells 104, e.g., by sensing a state of a data line connected to that memory cell. A status register 122 can be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of the memory device 130. In some implementations, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands can be received over input/output (I/O) pins [7:0] of I/O bus 134 at I/O control circuitry 160 and can then be written into command register 124. The addresses can be received over input/output (I/O) pins [7:0] of I/O bus 134 at I/O control circuitry 160 and can then be written into address register 114. The data can be received over input/output (I/O) pins [7:0] for an 8-bit device or input/output (I/O) pins [15:0] for a 16-bit device at I/O control circuitry 160 and then can be written into cache register 172. The data can be subsequently written into data register 170 for programming the array of memory cells 104.

In an implementation, cache register 172 can be omitted, and the data can be written directly into data register 170. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B can not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B.

Additionally, while specific I/O pins are described in accordance with popular conventions for receipt and output of the various signals, it is noted that other combinations or numbers of I/O pins (or other I/O node structures) can be used in the various implementations.

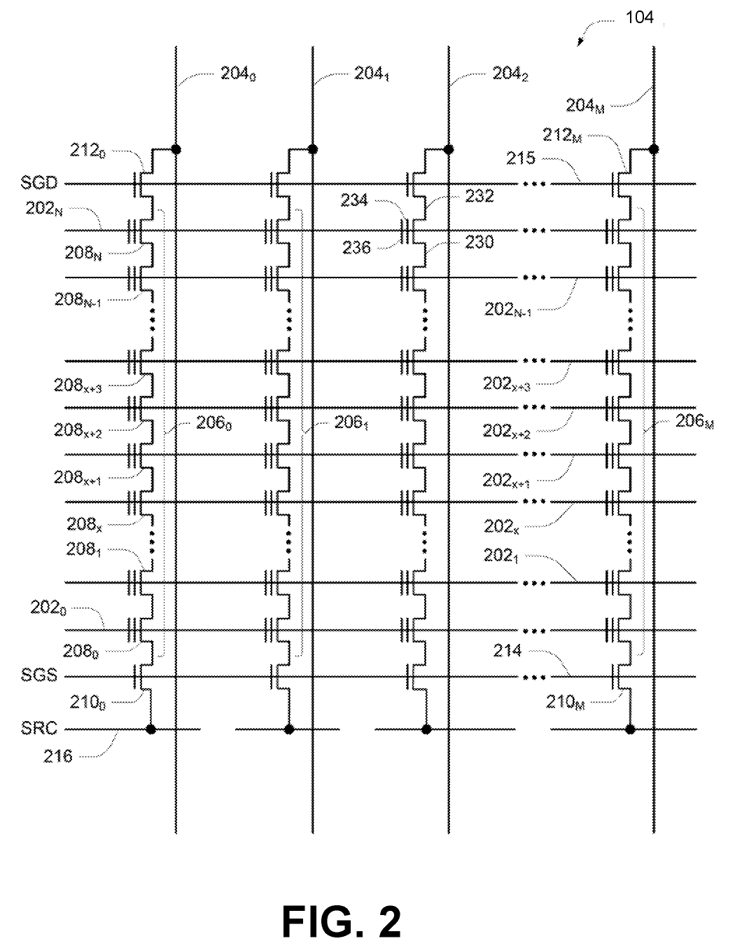

FIG. 2 is a schematic of portions of an example array of memory cells, in accordance with implementations of the present disclosure. Memory array 104 includes access lines, such as wordlines 202₀ to 202_{N}, and data lines, such as bitlines 204₀ to 204_{M}. The wordlines 202 can be connected to global access lines (e.g., global wordlines), not shown in FIG. 2, in a many-to-one relationship. For some implementations, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a respective source (SRC) segment (e.g., segment 216) and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to the source line 216. The drain of each select gate 210 can be connected to a memory cell 208₀ of the corresponding NAND string 206. For example, the drain of select gate 210₀ can be connected to memory cell 208₀ of the corresponding NAND string 206₀ . Therefore, each select gate 210 can be configured to selectively connect a corresponding NAND string 206 to the respective source segment 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 104 in FIG. 2 can be a quasi-two-dimensional memory array and can have a generally planar structure, e.g., where the source segments 216, NAND strings 206 and bitlines 204 extend in substantially parallel planes. Alternatively, the memory array 104 in FIG. 2 can be a three-dimensional memory array, e.g., where NAND strings 206 can extend substantially perpendicular to a plane containing the source segments 216 and to a plane containing the bitlines 204 that can be substantially parallel to the plane containing the source segments 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2, it is apparent from the figure that the bitlines 204 of the array of memory cells 104 can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some implementations, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the implementations and concepts described herein are not limited to a particular array architecture or structure, and can include other structures (e.g., SONOS, phase change, ferroelectric, etc.) and other architectures (e.g., AND arrays, NOR arrays, etc.).

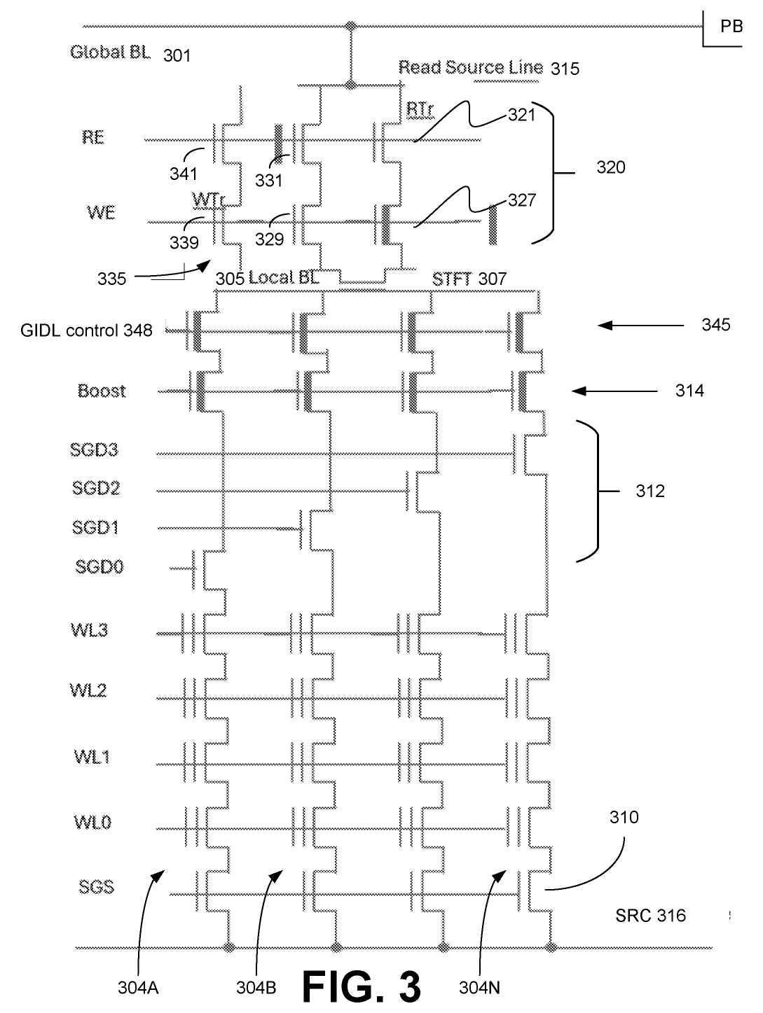

FIG. 3 is a schematic of portions of an example array of memory cells, in accordance with implementations of the present disclosure . In an illustrative example, the portion 300 of the memory array 104, can be a block 300 having multiple sub-blocks, each sub-block including multiple strings 304A-304N of memory cells coupled to a local bitline 305. The NAND strings 304A-304N can also be coupled to source select transistors 310, which are in turn coupled to a common source (SRC) 316, which in 3D NAND, can be a source plate layer.

In some implementations, the NAND strings 304A-304N are coupled through respective drain select transistors 312 coupled to the local bitline 305. Wordlines labeled as SGD0, SGD1, SGD2, SGD3 can be associated with the drain select transistors 312 that are respectively coupled to the NAND strings 304A-304N. In disclosed implementations, a combination of the source select transistors 310 and the drain select transistors 312 can be referred to jointly as select line transistors for simplicity.

In some implementations, the block 300 of memory array 104 includes a set of boost transistors 314, each coupled between the GIDL generator device 345 and a respective drain select transistors 312 of the respective NAND string 304A-304N. The boost transistors 314 can be enhanced-type transistors. In some implementations, wordlines labeled as WL0, WL1, WL2, WL3 are coupled to the memory cells of strings 304A-304N.

In some implementations, the block 300 of memory array 104 includes a sense transistor 307 (STFT) having a gate terminal coupled to the local bitline 305 and a series of transistors 320 that includes a data read path between a read source line 315 and the sense transistor 307 and between the sense transistor 307 and a global bitline 301. For example, this read data path can be controlled in order to read data states out of memory cells of the strings 304A-304N. In some implementations, the global bitline 301 is also coupled to a page buffer 352, such that the current over the read source line 315 can be read out by the page buffer 352 or other read circuitry.

In some implementations, the series of transistors 320 includes a first enhanced-type transistor 321 coupled with the read source line 315 and having a gate terminal coupled to a read-enable control line (RE). In some implementations, the series of transistors 320 includes a first depletion-type transistor 327 coupled between the first enhanced-type transistor 321 and a source of the sense transistor 307, the first depletion-type transistor having a gate terminal coupled with a write-enable control line (WE). In some implementations, the series of transistors 320 includes a second depletion-type transistor 329 coupled with a drain of the sense transistor 307 and has a gate terminal coupled to the write-enable control line (RE). In some implementations, the series of transistors 320 includes a second enhanced-type transistor 331 coupled between the second depletion-type transistor 329 and the global bitline 301, the second enhanced-type transistor having a gate terminal coupled with the read-enable control line (RE).

In some implementations, the block 300 of memory array 104 further includes a second series of transistors 335 forming a data write path, e.g., to be enabled to bias the local bitline 305 when writing data to the strings 304A-304N of memory cells. In some implementations, the second series of transistors 335 includes a third depletion-type transistor 341, which is coupled to the global bitline 301 in parallel with the series of transistors 320 and has a gate terminal also coupled with the read-enable control line (RE). In some implementations, the second series of transistors 335 includes a third enhanced-type transistor 339 (or write transistor, WTr) coupled between the third depletion-type transistor 341 and the local bitline 305 to form the above-mentioned data write path. In some implementations, a gate terminal of the third enhanced-type transistor 341 is coupled with the write-enable control line (WE).

In some implementations, the block 300 of memory array 104 includes one or more drain-side gate-induced drain leakage (GIDL) generator devices 345, which can be connected to a common gate line GIDL. In an illustrative example, the GIDL generator devices 345 can be located between the boost transistors 314 and the sense transistor 307 (STFT). The GIDL generator devices 345 can be employed to assist in the generation of the GIDL current into a channel region of the corresponding NAND string during an erase operation.

In the illustrative example of FIG. 3, the drain of the GIDL generator device 345 can be connected to the local bitline 305. The source of the GIDL generator device 345 can be connected, via the boost transistor 314, to a corresponding drain select transistors 312. Therefore, in cooperation, each drain select transistors 312, the boost transistor 313, and the GIDL generator device 345 for a corresponding NAND string 304A-304N can be employed to selectively connect that NAND string to the local bitline 305. The control gate of each GIDL generator device 345 can be connected to the GIDL control line 348.

In some implementations, the memory access manager 113 implemented by the memory sub-system controller 115 and/or local media controller 135 includes control logic coupled to the series of transistors 320, the set of boost transistors 314, and/or other components of the block 300 of memory array 104. In an illustrative example, the control logic can cause particular voltages to be applied to a certain wordline, to the local bitline 305, to select line transistors, to the local source line 315, etc.

As noted herein above, some memory operations, such as e.g., erase operations, involve applying a high voltage level (e.g., V_{PGM}, which is the programming voltage level) to the bitlines. That voltage would need to go through all select gates without significant drop, which would require driving the local select gates to a higher potential.

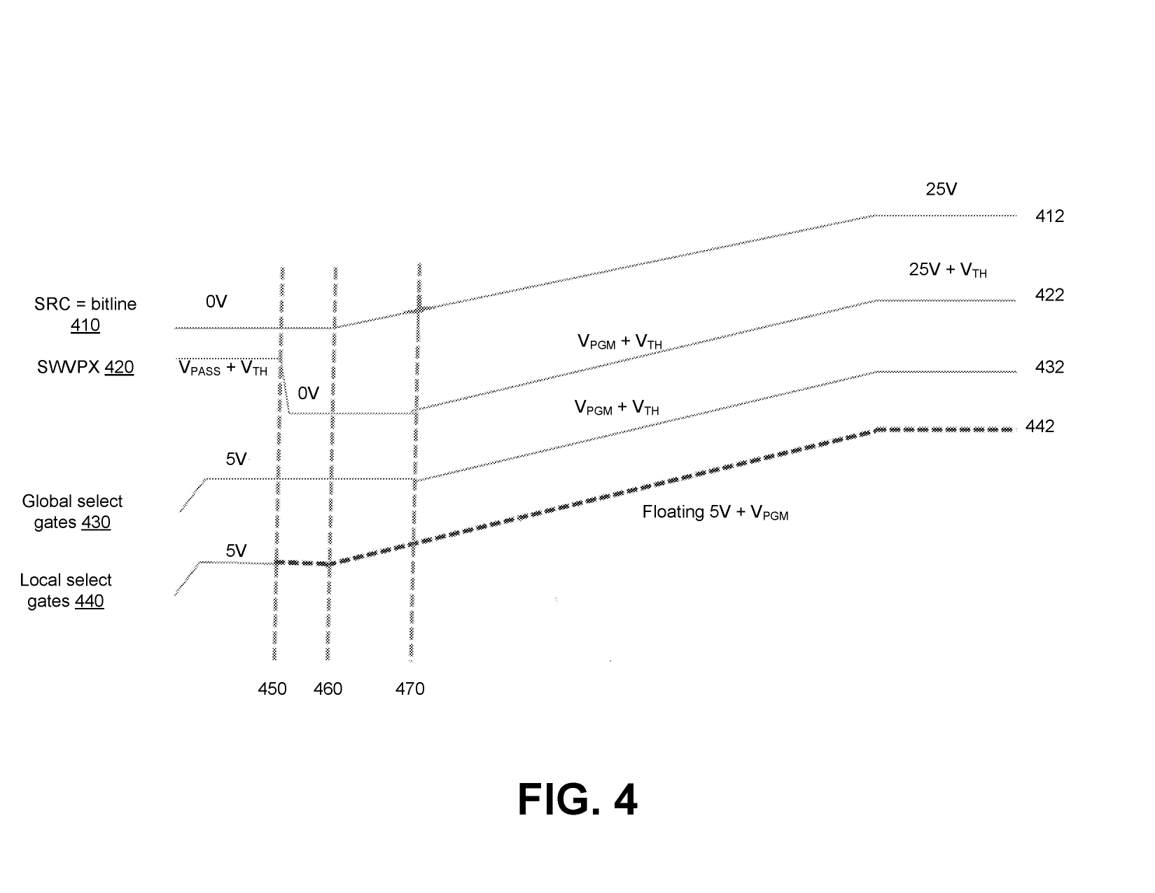

FIG. 4 schematically illustrates the voltage levels applied to various components of the memory device 130, in accordance with aspects of the present disclosure.

Line 410 schematically depicts the voltage level applied to one or more local bitlines and to the local source lines of the portion of the memory array. In the illustrative example of FIG. 4, the voltage level applied to one or more local bitlines and to the local source lines is driven from 0V to e.g., 25V (e.g., the highest voltage level available in the memory device).

Line 420 schematically depicts the gate voltage (SWVPX) of the string driver that connects local wordlines and select gates to global wordlines and select gates. The gate voltage can be determined as the sum of the threshold voltage V_{TH} of the string driver and the required voltage on the local wordlines and select gates. If the required voltage is VPGM, then VPGM+VTH voltage can be generated by a voltage generator and conveyed to the string driver. Accordingly, in the illustrative example of FIG. 4, the gate voltage SWVPX is tracking V_{PGM}, which is the erase voltage. In the illustrative example of FIG. 4, the targeted final value of V_{PGM} is 25V.

Line 440 schematically depicts the voltage level at the local select gates. The local select gates (e.g., SGD0-SGD3 and SGS) can be precharged to a predetermined voltage level, thus setting the conditions for proper coupling effects when the voltages are later applied to other components, as well as reducing leakages and unwanted disturbances in the unselected strings. In some implementations, the string drivers can apply the predetermined voltage (e.g., 5V) to the local select gates (e.g., SGD0-SGD3 and SGS) and hold the predetermined voltage level for a certain time period (e.g., between the points in time 450 and 460). The voltage level applied to the select gates can be determined based on the coupling ratio of the local select gates, in order to bring the erase voltage level (e.g., V_{PGM}) to the local source transistor 307, for successfully performing the erase operation.

Then, at the point in time 460, the string drivers can disconnect the local select gates from the voltage source, thus leaving the local select gates in the floating state. The local select gates would thus be coupled-up by the bitline, i.e., they will effectively track the voltage level of the bitline while maintaining the controlled voltage differential (e.g., 5V).

Line 430 schematically depicts the voltage level at the global select gates. The global select gates can be biased at a certain voltage level (e.g., V_{PGM} + V_{TH}, where V_{PGM} is the programming voltage level and V_{TH} is the threshold voltage level) in order to keep the string drivers isolated from the memory array.

In order to perform a memory erase operation, the wordlines of the selected block can be grounded (or a small negative bias -2-4V can be applied), thus forcing the removal of electrons from the floating gates. Upon completing the memory erase operation, the wordlines, bitlines, and select gates can be, e.g., driven to respective predefined voltage levels, grounded, or left in the floating state.

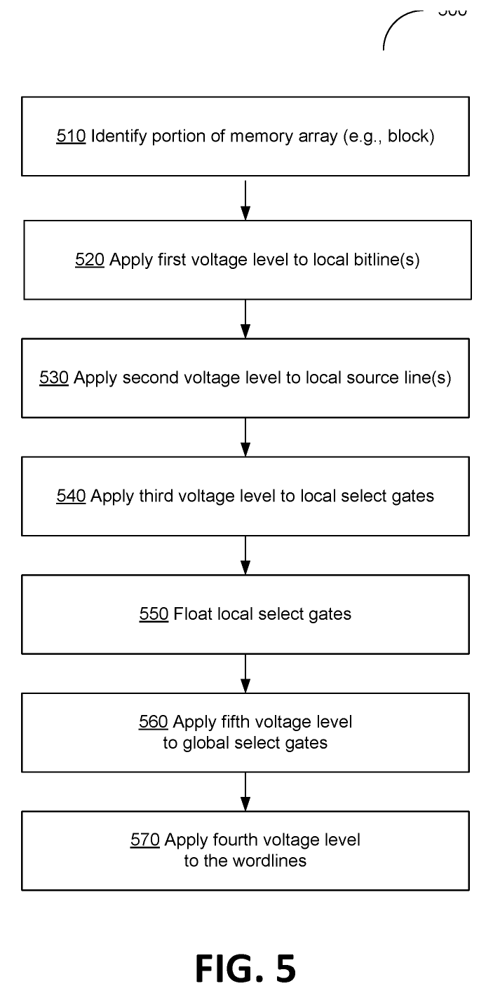

FIG. 5 is a flow diagram of an example method of performing erase operations in accordance with implementations of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some implementations, the method 500 is performed by the memory access manager 113 implemented by the memory sub-system controller 115 and or local media controller 135 of FIGS. 1A-1B. Although shown in a particular sequence or order, unless otherwise specified, the order of the processes can be modified. Thus, the illustrated implementations should be understood only as examples, and the illustrated processes can be performed in a different order, and some processes can be performed in parallel. Additionally, one or more processes can be omitted in various implementations. Thus, not all processes are required in every implementation. Other process flows are possible.

At operation 510, the processing device implementing the method identifies a portion (e.g., a block) of a memory array. In an illustrative example, the processing device may receive a memory command (e.g., an erase command) identifying a portion (e.g., a block) of the memory array. E ach portion of the memory array can include one or more strings of memory cells, such that each string of memory cells is electrically connected to a respective bitline via a first local select gate (e.g., the drain-side select gate (SGD)), and is also electrically connected to a respective source line via a second local select gate (e.g., the source-side select gate (SGS)). In some implementations, each portion of the memory array may include one or more global select gates (GSGs), such that each GSG electrically connects one or more local bitlines of the memory array to a global bitline. In some implementations, each portion of the memory array may include one or more gate-induced drain leakage (GIDL) generator devices, as described in more detail herein above.

At operation 520, the processing device causes a first voltage level (e.g., the programming voltage level, V_{PGM}) to be applied to one or more local bitlines of the identified portion of the memory array, as described in more detail herein above.

At operation 530, the processing device causes a second voltage level (e.g., the programming voltage level, V_{PGM}) to be applied to one or more local source lines of the identified portion of the memory array, as described in more detail herein above.

At operation 540, the processing device causes a third voltage level (e.g., a precharge voltage level of approximately 5V) to be applied to the local select gates of the identified portion of the memory array. The precharge voltage level applied to the local select gates may be held for a predetermined period of time in order to allow the select gates to be precharged, as described in more detail herein above.

At operation 550, the processing device causes the local select gates to transition to a floating state, thus causing the local select gates to be coupled-up by the local bitline, as described in more detail herein above.

At operation 560, the processing device causes a fifth voltage level (e.g., the sum of the programming voltage level V_{PGM} and the threshold voltage level V_{TH}) to be applied to the one or more global select gates of the memory array, in order to keep the string drivers isolated from the memory array, as described in more detail herein above.

At operation 570, the processing device causes a fourth voltage level (e.g., the ground voltage level of 0V or a small negative voltage of approximately -2-4V) to be applied to one or more wordlines of the identified portion of the memory array, thus causing removal of electrons from floating gates of the memory cells of the identified portion of the memory array, as described in more detail herein above.

Upon completing the memory erase operation, the wordlines, bitlines, and select gates can be, e.g., driven to respective predefined voltage levels, grounded, or left in the floating state.

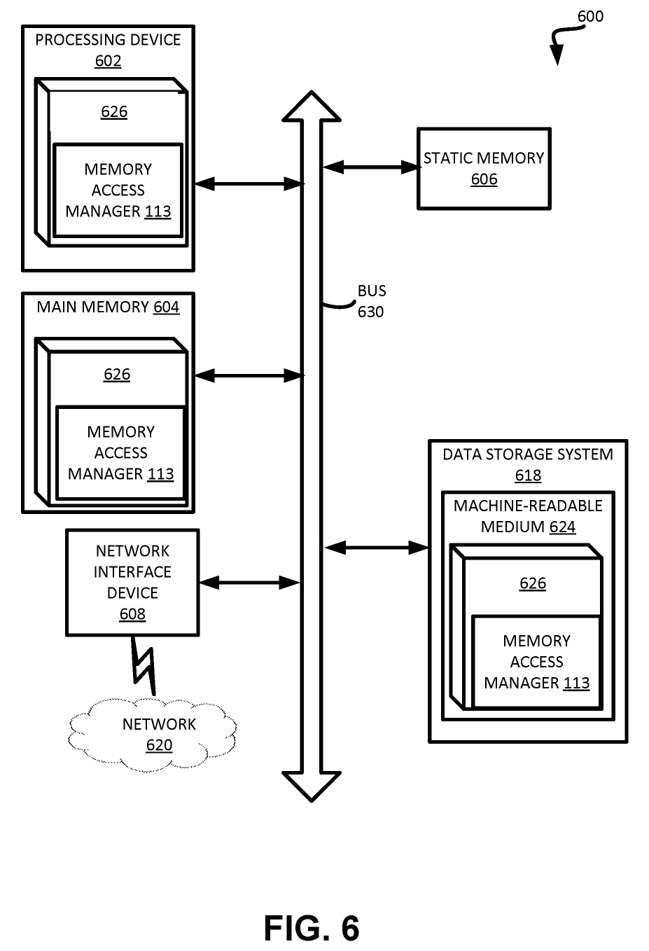

FIG. 6 illustrates an example machine of a computer system 600 within which a set of instructions, for causing the machine to perform any one or more of the methodologies discussed herein, can be executed. In some implementations, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the local media controller 135 of FIG. 1). In alternative implementations, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for implementing the memory access manager 113 and performing the operations of method 600 in accordance with implementations of the present disclosure. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In some implementations, the instructions 626 include instructions to implement functionality corresponding to the local media controller 135 of FIG. 1, including performing the sub-block erase operations in accordance with implementations of the present disclosure. While the machine-readable storage medium 624 is shown in an example implementation to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some implementations, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, implementations of the disclosure have been described with reference to specific example implementations thereof. It will be evident that various modifications can be made thereto without departing from the broader spirit and scope of implementations of the disclosure as set forth in the following claims. The specification and drawings are, accordingly, to be regarded in an illustrative sense rather than a restrictive sense.

What is claimed is:

1. A memory device, comprising:
a memory array comprising a plurality of portions, wherein each portion of the memory array comprises a plurality of strings of memory cells, wherein each string of the plurality of strings is coupled to a bitline via a first local select gate, and is further coupled to a source line via a second local select gate;
a processing device, operatively coupled to the memory array, the processing device configured to perform operations, comprising:
identifying a portion of the memory array;
causing a first voltage level to be applied to one or more local bitlines of the identified portion of the memory array;
causing a second voltage level to be applied to one or more local source lines of the identified portion of the memory array;
causing a third voltage level to be applied to a plurality of local select gates of the identified portion of the memory array;
causing the plurality of local select gates to transition to a floating state; and
causing a fourth voltage level to be applied to one or more wordlines of the identified portion of the memory array.

2. The memory device of claim 1, wherein each portion of the memory array is represented by a block.

3. The memory device of claim 1, wherein each portion of the memory array further comprises one or more gate-induced drain leakage (GIDL) generator devices.

4. The memory device of claim 1, further comprising: one or more global select gates, each select gate coupling a global bitline to a one or more local bitlines of the memory array.

5. The memory device of claim 4, wherein the operations further comprise:
responsive to causing the plurality of local select gates to transition to the floating state, causing a fifth voltage level to be applied to the one or more global select gates of the memory array.

6. The memory device of claim 4, wherein the fifth voltage level is a sum of programming voltage level and a threshold voltage level.

7. The memory device of claim 1, wherein each of the first voltage level and the second voltage level is a programming voltage level.

8. The memory device of claim 1, wherein the third voltage level is a precharge voltage level.

9. The memory device of claim 1, wherein the fourth voltage level is a ground voltage level.

10. The memory device of claim 1, wherein causing the plurality of local select gates to transition to the floating state causes the plurality of local select gates to be coupled-up by the bitline.

11. The memory device of claim 1, wherein identifying the portion of the memory array is performed responsive to receiving an erase command specifying the portion of the memory array.

12. The memory device of claim 1, wherein causing the fourth voltage level to be applied to one or more wordlines causes removal of electrons from floating gates of the memory cells of the identified portion of the memory array.

13. A method, comprising:
receiving, by a processing device, an erase command identifying a portion of a memory array;
causing a first voltage level to be applied to one or more local bitlines of the identified portion of the memory array;
causing a second voltage level to be applied to one or more local source lines of the identified portion of the memory array;
causing a third voltage level to be applied to a plurality of local select gates of the identified portion of the memory array;
causing the plurality of local select gates to transition to a floating state; and
causing a fourth voltage level to be applied to one or more wordlines of the identified portion of the memory array.

14. The method of claim 13, further comprising:
responsive to causing the plurality of local select gates to transition to the floating state, causing a fifth voltage level to be applied to one or more global select gates of the memory array.

15. The method of claim 14, wherein the fifth voltage level is a sum of programming voltage level and a threshold voltage level.

16. The method of claim 13, wherein each of the first voltage level and the second voltage level is a programming voltage level.

17. The method of claim 13, wherein the fourth voltage level is a ground voltage level.

18. A non-transitory computer readable storage medium comprising executable instructions that, when executed by a processing device, cause the processing device to perform operations, comprising:
identifying a portion of a memory array;
causing a first voltage level to be applied to one or more local bitlines of the identified portion of the memory array;
causing a second voltage level to be applied to one or more local source lines of the identified portion of the memory array;
causing a third voltage level to be applied to a plurality of local select gates of the identified portion of the memory array;
causing the plurality of local select gates to transition to a floating state; and
causing a fourth voltage level to be applied to one or more wordlines of the identified portion of the memory array.

19. The non-transitory computer readable storage medium of claim 18, wherein the operations further comprise:
responsive to causing the plurality of local select gates to transition to the floating state, causing a fifth voltage level to be applied to one or more global select gates of the memory array.

20. The non-transitory computer readable storage medium of claim 18, wherein identifying the portion of the memory array is performed responsive to receiving an erase command specifying the portion of the memory array.
